(19) United States
(12) Patent Application Publication
(10) Pub. No.: US 2005/0181543 A1
(43) Pub. Date: Aug. 18, 2005

(54) SEMICONDUCTOR PACKAGE MODULE AND MANUFACTURING METHOD THEREOF

(76) Inventors: Shih-Chang Lee, Kaohsiung (TW); Gwo-Liang Weng, Kaohsiung City (TW); Wei-Chang Tai, Kaohsiung City (TW); Cheng-Yin Lee, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,561

(22) Filed: Apr. 6, 2005

Related U.S. Application Data
(62) Division of application No. 10/604,791, filed on Aug. 18, 2003.

(30) Foreign Application Priority Data
Aug. 28, 2002 (TW) 91119483

(51) Int. Cl. H01L 21/44; H01L 21/48; H01L 21/50; H01L 23/48

(52) U.S. Cl. 438/127; 438/121; 438/124; 438/126

(57) ABSTRACT

A process for fabricating a multi-chip package module is disclosed. A substrate, at least a first chip and at least a second chip are provided. The backside of the first chip is attached to a die pad on a substrate. A wire-bonding operation is carried out to electrically connect the first chip and the substrate through conductive wires. A plurality of bumps is bonded to the second chip so that one end of each bump is bonded to a contact on the second chip. Thereafter, the other end of each bump is bonded to a contact on the substrate so that the second chip and the substrate are physically and electrically connected together. Finally, an encapsulation process is performed to form a packaging material enclosing the first chip, the second chip, the conductive wires, the bumps and the substrate.

### CROSS-REFERENCE TO RELATED APPLICATION

This application is a divisional of a prior application Ser. No. 10/604,791, filed Aug. 18, 2003, which claims the priority benefit of Taiwan application serial no. 91119483, filed on Aug. 28, 2002.

### BACKGROUND OF THE INVENTION

1. Field of the Invention

The present invention relates to a semiconductor package module and manufacturing method thereof. More particularly, the present invention relates to a semiconductor package module that can be manufactured using simplified manufacturing steps.

2. Description of the Related Art

With the rapid progress in manufacturing techniques in recent years, many high-tech, personalized and multi-functional electronic products are developed in the market. All these products are designed to be light, portable and compact. Thus, the semiconductor packaging industry often opts for a package capable of holding a multiple chips so that the overall occupation volume of the integrated circuits is reduced and electrical performance of each package is increased.

FIG. 1 is a schematic cross-sectional view of a conventional package module. The package module 100 in FIG. 1 has a substrate 110, a first chip 130 and a second chip 150. The substrate 110 has a plurality of first contacts 122, a plurality of second contacts 124 and a die pad 126, all of which are positioned on the substrate surface 112. The first contacts 122 are distributed around the die pad 126 and the second contacts 124 are positioned on the substrate surface 112 and organized in an array form.

The first chip 130 has a first active surface 132 and a corresponding backside 142. The first chip 130 has a plurality of first die contacts 134 positioned on the active surface 132. The backside 142 of the first chip 130 is attached to the die pad 126 through an adhesive material layer 144. The first chip 130 and the substrate 110 are electrically connected through conductive wires 150 in a wire-bonding operation. One end of each conductive wire 150 is bonded to one of the first contacts 122 while the other end of each conductive wire 150 is bonded to one of the die contacts 134. A packaging material 152 encloses the first chip 130, the conductive line 150 and the substrate surface 112 so that the first chip 130 and the conductive wires 150 are protected inside the packaging material 152.

The second chip 160 has a second active surface 162 and a corresponding backside 172. Furthermore, the second chip 160 has a plurality of second die contacts 164 positioned on the second active surface 162 and organized in an array form. The second active surface 162 faces the substrate surface 112 and the second chip 160 is physically and electrically connected to the substrate 110 via bumps 180. Each bump 180 has one end connected to one of the second die contacts 164 and the other end connected to one of the second contacts 124. An underfill material 182 is filled between the second chip surface 162 and the substrate surface 112 and encloses the bumps 180. By the formation of the underfill material 182, a portion of the stress resulting from a difference in the coefficient of thermal expansion between the substrate 110 and the second chip 160 is absorbed.

In the aforementioned fabrication process, separate steps are used to fabricate the packaging material 152 and the underfill material 182. Hence, the steps for forming the packaging material 152 and the underfill material 182 is complicated and inefficient. Moreover, serious warpage in the packaging module 100 frequently occurs because of the positional separate of the packaging material 152 from the underfill material 182.

### SUMMARY OF THE INVENTION

Accordingly, one object of the present invention is to provide a semiconductor package module and manufacturing method thereof that can simplify the packaging process.

A second object of this invention is to provide a semiconductor package module and manufacturing method thereof that can reduce the degree of warpage in the body of a multi-chip package module.

To achieve these and other advantages and in accordance with the purpose of the invention, as embodied and broadly described herein, this invention provides a process for fabricating a semiconductor package module. First, a substrate having a substrate surface is provided. The substrate has a plurality of first contacts, a plurality of second contacts and a die pad, all of which are positioned on the substrate surface. The first contacts are distributed around the die pad. A first chip having a first active surface and a corresponding first backside is also provided. The first chip has a plurality of first die contacts positioned on the first active surface. A second chip having a second active surface and a corresponding second backside is also provided. The second chip has a plurality of second die contacts positioned on the second active surface. Thereafter, the backside of the first chip is attached to the die pad. A wire-bonding operation is carried out to form a plurality of conductive wires electrically connecting the first chip and the substrate. One end of each conductive wire is bonded to one of the first contacts while the other end of the conductive wire is bonded to one of the first die contacts. A plurality of bumps are formed on the second chip wherein one end of each bump is bonded to one of the second die contacts while the other end of the bump is bonded to second contacts. Hence, the second chip is physically and electrically connected to the substrate. Finally, a packaging material is formed to enclose the first chip, the second chip, the conductive wires, the bumps and the substrate surface.

However, the fabrication of the semiconductor package module is not limited to the aforementioned process. In an alternative process, the second chip is connected to the substrate through the bumps before attaching the backside of the first chip to the die pad. Thereafter, the wire-bonding operation is carried out to form conductive wires linking up the first chip and the substrate electrically.

In one embodiment of this invention, the first chip can be a functional chip and the second chip can be a memory chip, for example. In addition, the backside of the second chip may be exposed outside the packaging material after the packaging material encloses the first chip, the second chip, the conductive wire, the bumps and the substrate surface. Thereafter, a heat sink is attached to the backside of the second chip and the packaging material around the second chip to boost the heat-dissipating capacity of the multi-chip module. Furthermore, the liquid temperature of the packaging material in the encapsulation process is preferably lower than the melting point of the bumps.

In brief, the semiconductor package module and manufacturing method thereof according to this invention only requires a single encapsulation step to form a packaging material enclosing the first chip, the second chip, the conductive wires and the bumps. Thus, both process time and manufacturing efficiency are boosted. Moreover, the packaging material encloses all of the first chip, the second chip, the conductive wires and the bumps, so the severity of warpage in the multi-chip package module will be greatly reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional package module.

FIG. 2 is a schematic cross-sectional view of a package module during one of the processing steps according to a first preferred embodiment of this invention.

FIG. 3 is a schematic cross-sectional view of a package module during one of the processing steps according to a second preferred embodiment of this invention.

FIG. 4 is a schematic cross-sectional view of a package module during another processing step according to the first preferred embodiment of this invention.

FIG. 5 is a schematic cross-sectional view of a package module during yet another processing step according to the first preferred embodiment of this invention.

FIG. 6 is a schematic cross-sectional view of a package module during yet another processing step according to the first preferred embodiment of this invention.

FIG. 7 is a schematic cross-sectional view of a multi-chip package module according to a third preferred embodiment of this invention.

FIG. 8 is a schematic cross-sectional view of a multi-chip package module according to a fourth preferred embodiment of this invention.

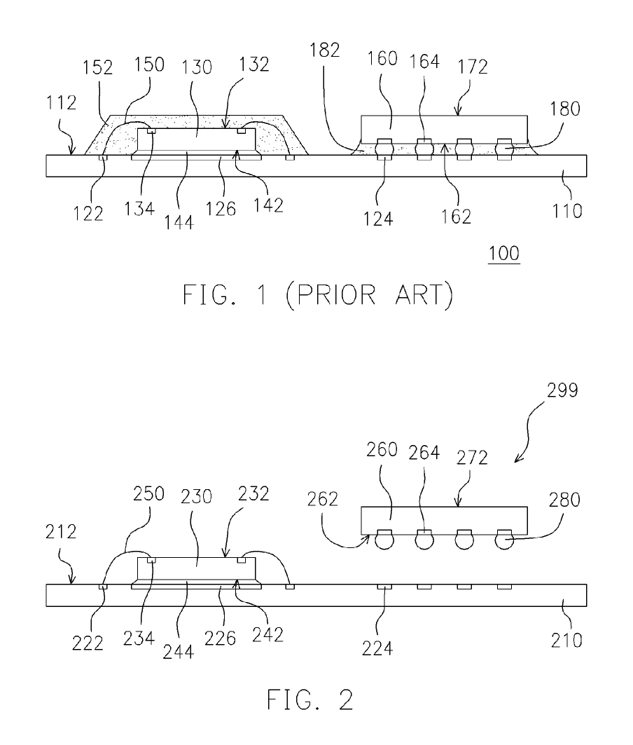

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIGS. 2, 4, 5 and 6 are schematic cross-sectional views showing the progression of steps for fabricating a multi-chip package module according to a first preferred embodiment of this invention. As shown in FIG. 2, a substrate 210 has a plurality of first contacts 222, a plurality of second contacts 224 and a die pad 226 on a substrate surface 212 thereof. The first contacts 222 surround the die pad 226 and the second contacts 224 are positioned on the substrate surface 212 and organized in an array form.

A chip 230 having an active surface 232 and a corresponding backside 242 is provided. The chip 230 can be a functional chip, such as a graphic chip or a control chip. A plurality of die contacts 234 is positioned on the active surface 232 of the chip 230. Thereafter, an adhesive material 244 is dispensed on the die pad 226 and then the backside 242 of the chip 230 is bonded to the die pad 226 via the adhesive material 244. A wire-bonding operation is carried out to form conductive wires 250 electrically connecting the chip 230 and the substrate 210. One end of each conductive wire 250 is bonded to one of the first contacts 222 on the substrate 210 while the other end of each conductive wire 250 is bonded to one of the die contacts 234 on the chip 230.

Thereafter, at least a package body 299 is provided. In this embodiment, the package body 299 has a chip 260 and a plurality of bumps 280. The chip 260 can be a memory chip such as a flash memory, a dynamic random access memory (DRAM) or a static random access memory (SRAM). The chip 260 has an active surface 262 and a corresponding backside 272. Furthermore, the chip 260 has a plurality of die contacts 264 positioned on the active surface 262 and organized in an array shape. One end of each bump 280 is connected to one of the die contacts 264.

A reflow process is carried out to join the package body 299 to the substrate 210. The other end of each bump 280 is bonded to a corresponding second contacts 224 on the substrate 210 so that the package body 299 is physically and electrically connected to the substrate 210. When the package body 299 and the substrate 210 are joined together, the active surface 262 of the chip 260 faces the substrate surface 212 as shown in FIG. 4.

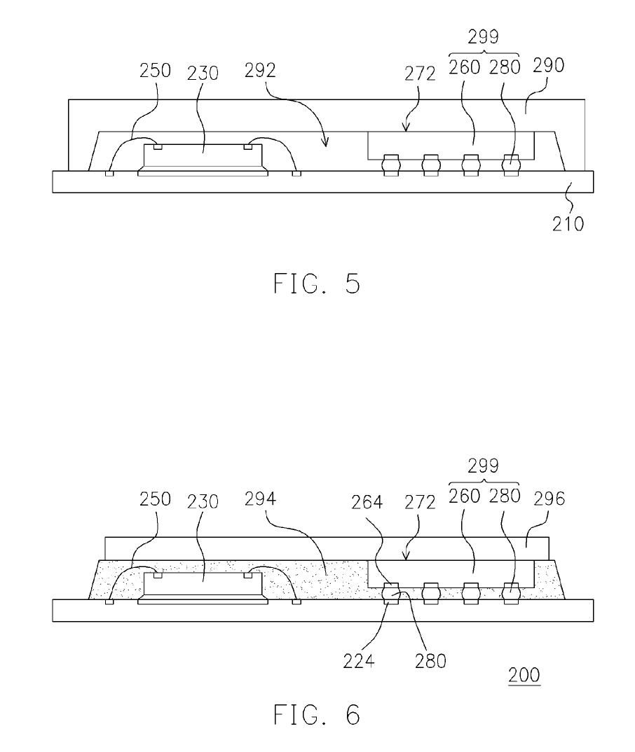

As shown in FIG. 5, the chip 230, the package body 299 and the substrate 210 are placed inside a mold 290. The mold 290 has a mold cavity 292 capable of accommodating the chip 230, the package body 299 and the conductive wires 250. Thereafter, a packaging material 294 is injected into the mold cavity 292 in an encapsulation process. After cooling and releasing the package body 299 from the mold 290, a structure as shown in FIG. 6 is formed. The packaging material 294 encloses the chip 230, the package body 299 and the substrate surface 212. So far, a multi-chip package 200 is completed. The packaging material 294 protects the chip 230, the chip 260 and the conductive wires 250. Furthermore, the packaging material 294 encloses the bumps 280 so that the stress between the substrate 210 and the chip 260 due to a difference in the coefficient of thermal expansion thereof can be partially absorbed by the packaging material 294. The liquid temperature of the packaging material 294 in the encapsulation process is preferably lower than the melting point of the bumps 280. In addition, in the encapsulation process, the backside 272 may be pressed on the bottom section of the cavity 292 so that none of the packaging material 294 will flow into the gap between the backside 272 of the chip 260 and the bottom section of the cavity 292. With this setup, the chip backside 272 is exposed outside the packaging material 294 for boosting the dissipation of heat from the chip 260. Moreover, a heat sink 296 may be optionally attached to the chip backside 272 and the surface of the packaging material 294 around the chip 260 to enhance the heat-dissipating rate.

In this invention, a single encapsulation process is used to form the packaging material 294 enclosing the chip 230, the chip 260, the conductive wires 250 and the bumps 280. Thus, the process is able to increase packaging yield and lower production cost. Moreover, because of the packaging material 294 enclosing the chip 230, the chip 260, the conductive wires 250 and the bumps 280, warpage of the package module 200 is also greatly reduced. In addition, because the bumps 280 are enclosed by the packaging material 294, the reliability of the connections between the bumps 280 and the die contacts 264 and between the bumps 280 and the second contacts 224 on the substrate 210 is improved. It is noted that before the chips 230 and 260 are mounted on the substrate 210, the chips 230 and 260 can be tested.

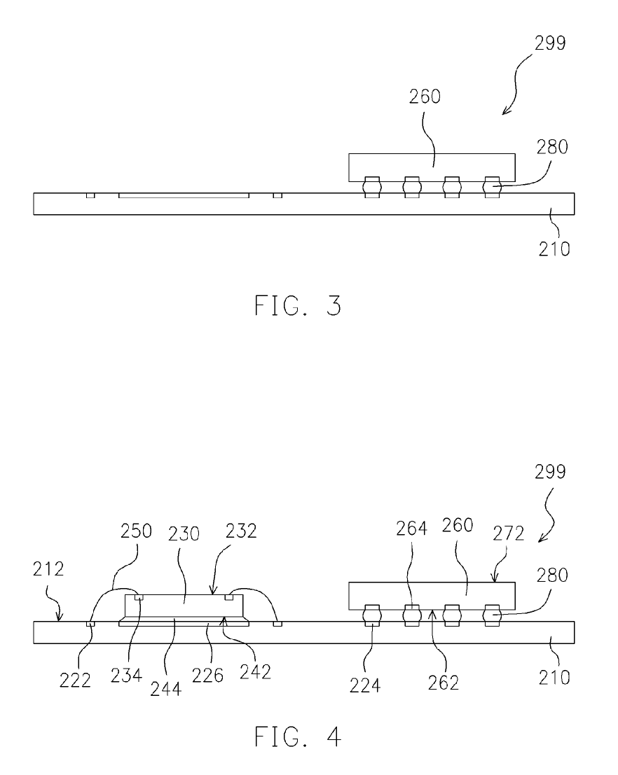

In the aforementioned fabrication process, a chip is bonded to the substrate and then the chip is electrically connected to the substrate through conductive wires in a wire-bonding operation before electrically and physically connecting a package body to the substrate via bumps. However, this invention also permits other modes of fabricating the multi-chip package module. FIG. 3 is a schematic cross-sectional view of a package module during one of the processing steps according to a second preferred embodiment of this invention. For example, as shown in FIGS. 3, 4, 5 and 6, a package body 299 is attached to a substrate 210 via bumps 280 before attaching the backside 242 of the chip 230 to the die pad 226. Next, a wire-bonding operation is carried out to form conductive wires 250 electrically connecting the chip 230 and the substrate 210. Thereafter, an encapsulation process similar to the above-mentioned is carried out and details are not repeated here.

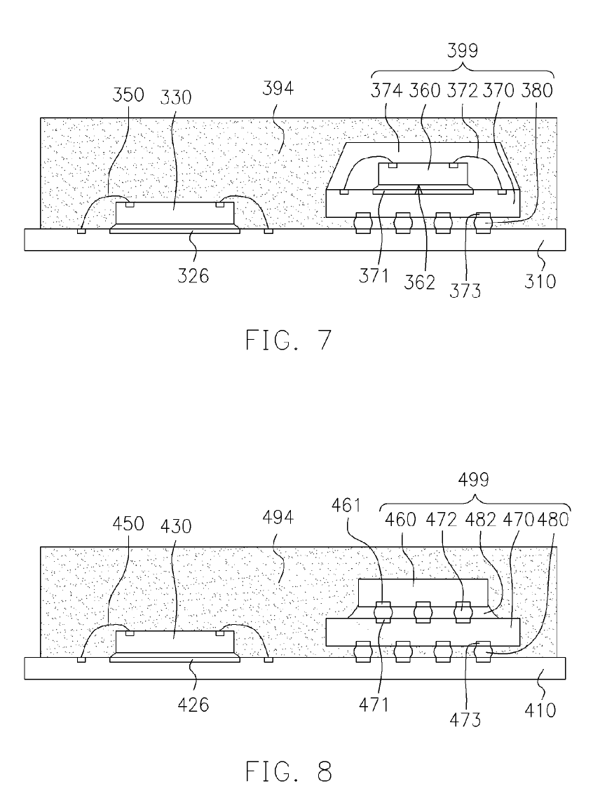

Furthermore, in the aforementioned embodiment, the package body comprises a chip and a plurality of bumps. Yet, other types of package bodies can also be enclosed inside the multi-chip package module according to this invention. FIG. 7 is a schematic cross-sectional view of a multi-chip package module according to a third preferred embodiment of this invention. As shown in FIG. 7, the package body 399 has a chip 360, a carrier 370, a plurality of bumps 380, a plurality of additional conductive wires 372 and an additional package material 374. The backside 362 of the chip 360 is attached to a die pad 371 on the carrier 370. The chip 360 and the carrier 370 are electrically connected through a plurality of additional conductive wires 372. The additional package material 374 encloses the chip 360, the additional conductive wires 372 and the carrier 370. One end of each bump 380 is bonded to one of the contacts 373 of the carrier 370.

To fabricate the multi-chip package module as shown in FIG. 7, the chip 330 is attached to the die pad 326 of the substrate 310 and then the chip 330 and the substrate 310 are electrically connected through the conductive wires 350 formed in a wire-bonding operation. Thereafter, a reflow process is performed to connect the package body 399 to the substrate 310 both physically and electrically via the bumps 380. Finally, an encapsulation process is carried out to form a packaging material 394 encapsulating the chip 330, the additional package material 374 of the package body 399, the bumps 380 of the package body 399, the carrier 370 of the package body 399, the additional conductive wires 350 and the substrate 310. Alternatively, a reflow process is carried out so that the package body 399 and the substrate 310 are electrically and physically connected via the bumps 380 before attaching the chip 330 to the die pad 326 on the substrate 310. Thereafter, a wire-bonding operation is carried out to form conductive wires 350 electrically connecting the chip 330 and the substrate 310. Finally, an encapsulation process is carried out to form a packaging material 394 enclosing the chip 330, the additional packaging material 374 of the package body 399, the bumps 380 of the package body 399, the carrier 370 of the package body 399, the conductive wires 350 and the substrate 310.

FIG. 8 is a schematic cross-sectional view of a multi-chip package module according to a fourth preferred embodiment of this invention. As shown in FIG. 8, the package body 499 comprises a chip 460, a carrier 470, a plurality of additional bumps 472, an underfill material layer 482 and a plurality of bumps 480. The chip 460 is physically and electrically connected to the carrier 470 via the additional bumps 472. One end of each additional bump 472 is bonded to one of the die contacts 461 while the other end of each bump 472 is bonded to one of the contacts 471 on the carrier 470. The underfill material layer 482 is filled between the chip 460 and the carrier 470 and encloses the additional bumps 472. One end of each bump 480 is bonded to one of the contacts 473 on the carrier 470.

To fabricate the multi-chip package module as shown in FIG. 8, the chip 430 is attached to the die pad 426 of the substrate 410 and then the chip 430 and the substrate 410 are electrically connected through conductive wires 450 formed in a wire-bonding operation. Thereafter, a reflow process is performed to physically and electrically connect the package body 499 to the substrate 410 both via the bumps 480. Finally, an encapsulation process is carried out to form the packaging material 494 encapsulating the chip 430, the chip 460 of the package body 499, the bumps 480 of the package body 499, the carrier 470 of the package body 499, the conductive wires 450 and the substrate 410. Alternatively, a reflow process is carried out so that the package body 499 and the substrate 410 are electrically and physically connected via the bumps 480 before attaching the chip 430 to the die pad 426 on the substrate 410. Thereafter, a wire-bonding operation is carried out to form conductive wires 450 electrically connecting the chip 430 and the substrate 410. Finally, an encapsulation process is carried out to form the packaging material 494 enclosing the chip 430, the chip 460 of the package body 499, the bumps 480 of the package body 499, the carrier 470 of the package body 499, the conductive wires 450 and the substrate 410. Due to the formation of the packaging material 494, reliability of the bonds between the bumps 480 and the carrier 470 and between the bumps 480 and the substrate 410 is greatly improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A process for fabricating a multi-chip package module, comprising the steps of:
providing a substrate;
providing a first chip;
providing a package body having a plurality of bumps, wherein the package body has at least one chip mounted on a carrier and enclosed by a first packaging material;
attaching the first chip to the substrate;
bonding a plurality of conductive wires so that the first chip and the substrate are electrically connected;
bonding the package body to the substrate through the bumps; and
performing an encapsulation process by a second packaging material that encloses the first chip, the conductive wires, the package body and the substrate.

2. The process of claim 1, wherein the first chip is a functional chip.

3. The process of claim 1, wherein the at least one chip in the package body has a second chip electrically connected to the bumps.

4. The process of claim 3, wherein the second chip is a memory chip.

5. The process of claim 3, wherein the second chip is partially enclosed by the second packaging material.

6. The process of claim 1, wherein after performing the encapsulation process, a heat sink is attached onto the package body, either contacting with the second chip or non-contacting with the second chip.

7. The process of claim 1, wherein after performing the encapsulation process, a heat sink is attached onto a surface of the second packaging material.

8. The process of claim 1, wherein after attaching the first chip to the substrate, the conductive wires are bonded to electrically connect the first chip with the substrate, and then the package body is attached to the substrate through the bumps.

9. The process of claim 1, wherein after the step of attaching the package body to the substrate through the bumps, the first chip is attached onto the substrate, and then the conductive wires are bonded to electrically connect the first chip with the substrate.

10. The process of claim 1, wherein a liquid temperature of the second packaging material in the encapsulation process is lower than a melting point of the bumps.
